(19) United States
(12) Patent Application Publication
(10) Pub. No.: US 2025/0141176 A1
(43) Pub. Date: May 1, 2025

(54) SCALABLE COHERENT LASER ARRAY SYSTEMS

(71) Applicant: The MITRE Corporation, McLean, VA (US)

(72) Inventors: Robert HOUVENER, Hollis, NH (US); Greg CARDINALE, Duxbury, MA (US); Rory LAMOND, Washington, DC (US); Michael STENNER, Vienna, VA (US); Dan MORIARTY, Nashua, NH (US); Chenglong ZHAO, Falls Church, VA (US); Dennis GARDNER, JR., Falls Church, VA (US)

(73) Assignee: The MITRE Corporation, McLean, VA (US)

(21) Appl. No.: 18/927,444

(22) Filed: Oct. 25, 2024

Related U.S. Application Data
(60) Provisional application No. 63/593,748, filed on Oct. 27, 2023.

(51) Int. Cl. H01S 3/23; H01S 3/063; H01S 3/10; H01S 5/11; H01S 5/42

(52) U.S. Cl. CPC H01S 3/2383; H01S 3/063; H01S 3/10092; H01S 5/11; H01S 5/423

(57) ABSTRACT

A laser system may include a laser array comprising a plurality of laser array emitters and a seed laser. The seed laser may be positioned on and directed toward an emitting side of the laser array or may be optically coupled to the plurality of laser array emitters by a waveguide bordering the laser array. The seed laser may be configured to emit a seed beam that interferes with one or more array beams emitted by one or more of the laser array emitters and locks the one or more array beams to a phase of the seed beam. An adjustable micro-lens array positioned on an emitting side of the laser array may enable laser array beams to be steered to a target location.

### CROSS-REFERENCE TO RELATED APPLICATION

This application claims the benefit of U.S. Provisional Application No. 63/593,748, filed Oct. 27, 2023, the entire contents of which is incorporated herein by reference.

### FIELD

The present disclosure relates to systems and methods for generating coherent emission from laser arrays.

### BACKGROUND

Laser systems are used in numerous commercial and government applications to wirelessly transmit energy between two locations. Defense agencies, for example, may use laser systems to disable hostile targets from a safe distance, while manufacturing companies may use laser systems to precisely cut and shape consumer products.

Arrays of laser emitters can generate beams that have cumulatively higher power than those produced by individual lasers. These high-power beams are produced by combining light from multiple emitters. To prevent energy losses when the emitter beams are combined, each emitter beam must be identical to every other emitter beam, i.e., the laser emitters in the array must be coherent. If the emitters in an array are non-coherent, the beam diverges too much as it propagates towards the target, restricting the overall power delivery of the laser array.

### SUMMARY

In order to generate high-power emission from a laser array, each emitter in the laser array must produce a beam that is coherent with every other beam produced by every other emitter in the laser array. That is, there must be a fixed relationship between the electrical fields and phases of the individual beams. Achieving coherence can be challenging; conventional systems for producing coherent emission from a laser array may be expensive, unwieldy, and difficult to adapt for use with mobile equipment or in compact spaces. Furthermore, overheating risks may limit the power output enabled by conventional systems to watt or kilowatt ranges. Therefore, there is need for efficient and adaptable laser array systems that can generate coherent emission in ranges beyond the kilowatt range.

Described herein are laser array systems that produce highly coherent and controllable beams by locking each of the beams generated by individual laser emitters to an identical optical phase. This phase-locking of the array beams may be achieved by injecting a seed beam produced by a seed laser into the lasers in the array. As the seed beam interacts with each laser in the array, the phases of the array beams may evolve until they match the phase of the seed beam. Once phase-locked, the array beams may be combined with minimal destructive interference and used to transmit high amounts of power (in ranges up to and exceeding the megawatt range) to a target or receiver.

The position of the seed laser relative to the laser array in the described systems may reduce manufacturing costs associated with the system while increasing the adaptability and overall efficiency of the system. In one implementation of the laser array system, for example, the seed laser may be positioned in the same plane as the laser array. The seed laser may be optically coupled to the laser array emitters by a waveguide that borders the laser array on one side. This configuration may minimize the overall system volume, thereby improving the system's portability and applicability. In another implementation, the seed laser may be positioned on an emitting side of the laser array. Subject to this constraint, users may freely adjust the location of the seed laser, allowing the system to be implemented in compact or uniquely shaped spaces. In all cases, the seed laser may be positioned such that heat can radiate freely from the laser array while the system is in use, reducing the need for expensive and bulky cooling and thermal management equipment and lowering the risk of damage to the system components due to overheating.

Optical elements for controlling the phase or direction of the seed beam may be included. These optical elements may allow properties of the seed beam to be tailored to address specific spatial regions of, or specific emitters in, the laser array. This localized control may allow the system to produce highly coherent beams and, as a result, increase the system's power at the target.

In addition to the phase-locking laser array systems, a beam steering system for controlling the directions and phases of array beams produced by a laser array is provided. The beam steering system may include a micro-lens array positioned on an emitting side of the laser array. The position of the micro-lens array relative to the laser array may be adjusted as array beams emitted by the laser array emitters propagate through the micro-lenses to change and control the direction of the array beams. Thus, the beam steering system may be used to redirect array beams emitted by a laser array to a target of interest. Phase-sensing and phase-changing elements for sensing and controlling (respectively) the phases of each array beam as it passes through the beam steering system may also be in included, potentially enabling array beams that have been locked to one optical phase (e.g., using a phase-locking laser array system described herein) to be fine-tuned before being transmitted to a target or receiver.

A first laser system provided herein may comprise a laser array comprising a plurality of laser array emitters, a seed laser, and a waveguide bordering the laser array and configured to optically couple the seed laser to the plurality of laser array emitters. The seed laser may be configured to emit a seed beam that interferes with one or more array beams emitted by the one or more of the plurality of laser array emitters and locks the one or more array beams to a phase of the seed beam.

In the first laser system, the laser array may be a two-dimensional laser array. The plurality of laser array emitters may include vertical-cavity surface-emitting lasers (VCSELs) or photonic crystal surface-emitting lasers (PCSELs). The waveguide in the first laser array may be linear in shape. The waveguide may comprise aluminum gallium arsenide.

The waveguide in the first laser system may include one or more partial pass deflectors configured to deflect the seed beam to one or more spatial regions of the laser array. One or more phase-changing elements may be positioned in an optical path of the seed laser and configured to change the phase of the seed beam. Each phase-changing element of the one or more phase-changing elements may be positioned next to a laser array emitter of the plurality of laser array emitters. The one or more phase-changing elements may comprise a material having a physical property that changes when a voltage is applied to the material, wherein the change in the physical property of the material induces a change in the phase of the seed beam when the seed beam propagates through the phase-changing element. The one or more phase-changing elements may be electro-optic modulators or piezoelectric devices. A voltage source may be electrically coupled to the one or more phase changing elements. The first laser system may include one or more processors configured to control the voltage source. The one or more processors may be wirelessly coupled to the voltage source.

A first method provided herein may comprise propagating a seed beam emitted by a seed laser through a waveguide bordering a laser array comprising a plurality of laser array emitters and interfering the seed beam with one or more laser array beams emitted by one or more of the plurality of laser array emitters to lock the one or more laser array beams to a phase of the seed beam. The first method can further comprise deflecting the seed beam to one or more spatial regions of the laser array using one or more partial-pass deflectors embedded in the waveguide. Additionally, the first method can involve changing a phase of the seed beam using one or more phase-changing elements prior to interfering the seed beam with at least one laser array beam of the one or more laser array beams. Changing the phase of the seed beam using a phase-changing element of the one or more phase-changing elements may comprise transmitting the seed beam through the phase-changing element and applying a voltage to the phase-changing element using a voltage source to cause a physical property of the phase-changing element to change. The change in the physical property may induce a change in the phase of the seed beam.

A second laser system described herein may comprise a laser array comprising a plurality of laser array emitters and a seed laser positioned on an emitting side of the laser array. The seed laser may be configured to emit a seed beam that interferes with one or more array beams emitted by the one or more of the plurality of laser array emitters and locks the one or more array beams to a phase of the seed beam.

In the second laser system, a position of the seed laser is offset from optical paths of the one or more array beams. The seed laser may be directed away from the emitting side of the laser array. The second laser system can include a frame, and the seed laser may be attached to the frame. The seed laser may be movable between a plurality of positions along the frame.

The second laser system may include one or more reflectors configured to redirect the seed beam to the emitting side of the laser array. An optical routing element may be positioned on the emitting side of the laser array and configured to direct the seed beam to a first laser array emitter of the plurality of laser array emitters. The optical routing element may be a diffraction grating or a micro-lens.

The second laser system can include one or more phase-changing elements positioned on an emitting side of the laser array and configured to change the phase of the seed beam. The one or more phase-changing elements may comprise a material having a physical property that changes when a voltage is applied to the material, wherein the change in the physical property of the material induces a change in the phase of the seed beam when the seed beam propagates through the phase-changing element. The one or more phase-changing elements may be electro-optic modulators or piezoelectric devices. A voltage source may be electrically coupled to the one or more phase changing elements. The second laser system may include one or more processors configured to control the voltage source may be included in the second laser system. The one or more processors may be wirelessly coupled to the voltage source.

The laser array in the second laser array system may be a two-dimensional laser array. The laser array emitters may comprise vertical-cavity surface-emitting lasers (VCSELs) or photonic crystal surface-emitting lasers (PCSELs).

A second method provided herein may comprise propagating a seed beam emitted by a seed laser to an emitting side of a laser array comprising plurality of laser array emitters and interfering the seed beam with one or more laser array beams emitted by one or more of the plurality of laser array emitters to lock the one or more array beams to a phase of the seed beam. Propagating the seed beam to an emitting side of the laser array may comprise transmitting the seed beam to a reflector and redirecting the seed beam to the emitting side of the laser array using the reflector. Interfering the seed beam with a laser array beam emitted by a first laser array emitter of the plurality of laser array emitters may involve receiving the seed beam with an optical routing element positioned on the emitting side of the laser array and directing the seed beam to the first laser array emitter using the optical routing element.

The second method can further comprise changing a phase of the seed beam using one or more phase-changing elements prior to interfering the seed beam with at least one laser array beam of the one or more laser array beams. Changing the phase of the seed beam using a phase-changing element of the one or more phase-changing elements comprises transmitting the seed beam through the phase-changing element and applying a voltage to the phase-changing element using a voltage source to cause a physical property of the phase-changing element to change, wherein the change in the physical property induces a change in the phase of the seed beam.

A laser array steering system may comprise a laser array comprising a plurality of laser array emitters, a micro-lens array positioned on an emitting side of the laser array and comprising a plurality of micro-lenses, an actuator connected to and configured to adjust a position of the micro-lens array relative to the laser array, and one or more processors configured to control the actuator.

The plurality of laser array emitters in the laser array steering system may comprise vertical-cavity surface-emitting lasers (VCSELs) or photonic crystal surface-emitting lasers (PCSELs). The actuator may include a micro-electromechanical system or a translation stage. The translation stage can comprise a servo or a piezoelectric device. The one or more processors may be configured to cause the actuator to adjust the position of the micro-lens array based on a location of a target and a separation distance between the micro-lens array and the laser array.

The laser array steering system can include one or more phase-changing elements positioned on an emitting side of the laser array and configured to induce phase changes in array beams emitted by one or more of the plurality of laser array emitters. The one or more phase-changing elements may comprise a material having a physical property that changes when a voltage is applied to the material, wherein the change in the physical property of the material induces a change in the phase of an array beam when the array beam propagates through the phase-changing element. The one or more phase-changing elements may be electro-optic modulators or piezoelectric devices. A voltage source may be electrically coupled to the one or more phase-changing elements. The one or more processors may be configured to control the voltage source. The one or more processors can be wirelessly coupled to the voltage source.

A third method described herein may comprise receiving one or more laser array beams emitted by one or more laser array emitters in a laser array at one or more micro-lenses of a micro-lens array positioned on an emitting side of the laser array and adjusting a position of the micro-lens array relative to the laser array to steer the one or more laser array beams to a target location. Adjusting the position of the micro-lens array relative to the laser array may comprise transmitting a signal to an actuator connected to the micro-lens array using one or more processors. The signal may cause the actuator to adjust the position of the micro-lens array based on a location of a target and a separation distance between the micro-lens array and the laser array.

The third method can further comprise changing a phase of a laser array beam of the one or more laser array beams using a phase-changing element. Changing the phase of the laser array beam using the phase-changing element may involve transmitting the laser array beam through the phase-changing element and applying a voltage to the phase-changing element using a voltage source to cause a physical property of the phase-changing element to change, wherein the change in the physical property induces a change in the phase of the seed beam.

In some embodiments, a laser system is provided, comprising: a laser array comprising a plurality of laser array emitters; a seed laser; and a waveguide bordering the laser array and configured to optically couple the seed laser to the plurality of laser array emitters, wherein the seed laser is configured to emit a seed beam that interferes with one or more array beams emitted by the one or more of the plurality of laser array emitters and locks the one or more array beams to a phase of the seed beam. In some embodiments of the laser system, the waveguide is linear in shape. In some embodiments of the laser system, the laser array is a two-dimensional laser array. In some embodiments of the laser system, the waveguide comprises one or more partial pass deflectors configured to deflect the seed beam to one or more spatial regions of the laser array. In some embodiments of the laser system, the laser system comprises one or more phase-changing elements positioned in an optical path of the seed laser and configured to change the phase of the seed beam. In some embodiments of the laser system, each phase-changing element of the one or more phase-changing elements is positioned next to a laser array emitter of the plurality of laser array emitters. In some embodiments of the laser system, the one or more phase-changing elements comprise a material having a physical property that changes when a voltage is applied to the material, wherein the change in the physical property of the material induces a change in the phase of the seed beam when the seed beam propagates through the phase-changing element. In some embodiments of the laser system, the one or more phase-changing elements are electro-optic modulators or piezoelectric devices. In some embodiments of the laser system, the laser system comprises: a voltage source electrically coupled to the one or more phase changing elements; and one or more processors configured to control the voltage source. In some embodiments of the laser system, the one or more processors are wirelessly coupled to the voltage source. In some embodiments of the laser system, the plurality of laser array emitters comprise vertical-cavity surface-emitting lasers (VCSELs) or photonic crystal surface-emitting lasers (PCSELs). In some embodiments of the laser system, the waveguide comprises aluminum gallium arsenide.

In some embodiments, a method is provided, comprising: propagating a seed beam emitted by a seed laser through a waveguide bordering a laser array comprising a plurality of laser array emitters; and interfering the seed beam with one or more laser array beams emitted by one or more of the plurality of laser array emitters to lock the one or more laser array beams to a phase of the seed beam. In some embodiments of the method, the method comprises deflecting the seed beam to one or more spatial regions of the laser array using one or more partial-pass deflectors embedded in the waveguide. In some embodiments of the method, the method comprises changing a phase of the seed beam using one or more phase-changing elements prior to interfering the seed beam with at least one laser array beam of the one or more laser array beams. In some embodiments of the method, changing the phase of the seed beam using a phase-changing element of the one or more phase-changing elements comprises: transmitting the seed beam through the phase-changing element; and applying a voltage to the phase-changing element using a voltage source to cause a physical property of the phase-changing element to change, wherein the change in the physical property induces a change in the phase of the seed beam.

In some embodiments, a laser system is provided, comprising: a laser array comprising a plurality of laser array emitters; and a seed laser positioned on an emitting side of the laser array; wherein the seed laser is configured to emit a seed beam that interferes with one or more array beams emitted by the one or more of the plurality of laser array emitters and locks the one or more array beams to a phase of the seed beam. In some embodiments of the laser system, a position of the seed laser is offset from optical paths of the one or more array beams. In some embodiments of the laser system, the seed laser is directed away from the emitting side of the laser array, and the system comprises one or more reflectors configured to redirect the seed beam to the emitting side of the laser array. In some embodiments of the laser system, the laser system comprises an optical routing element positioned on the emitting side of the laser array and configured to direct the seed beam to a first laser array emitter of the plurality of laser array emitters. In some embodiments of the laser system, the optical routing element is a diffraction grating. In some embodiments of the laser system, the optical routing element is a micro-lens. In some embodiments of the laser system, the laser system comprises one or more phase-changing elements positioned on an emitting side of the laser array and configured to change the phase of the seed beam. In some embodiments of the laser system, the one or more phase-changing elements comprise a material having a physical property that changes when a voltage is applied to the material, wherein the change in the physical property of the material induces a change in the phase of the seed beam when the seed beam propagates through the phase-changing element.

In some embodiments of the laser system, the one or more phase-changing elements are electro-optic modulators or piezoelectric devices. In some embodiments of the laser system, the laser system comprises: a voltage source electrically coupled to the one or more phase changing elements; and one or more processors configured to control the voltage source. In some embodiments of the laser system, the one or more processors are wirelessly coupled to the voltage source. In some embodiments of the laser system, the laser system comprises a frame, wherein the seed laser is attached to the frame. In some embodiments of the laser system, the seed laser is movable between a plurality of positions along the frame. In some embodiments of the laser system, the laser array emitters comprise vertical-cavity surface-emitting lasers (VCSELs) or photonic crystal surface-emitting lasers (PCSELs). In some embodiments of the laser system, the laser array is a two-dimensional laser array. In some embodiments of the laser system, the seed beam forms a seeding angle θ_{seed} of incidence with respect to the laser array, the one or more array beams form a steering angle θₛₜₑₑᵣ with respect to the laser array, and the steering angle and seeding angle comply with the following: for the steering angle:

$$( - \frac{λ}{π a} < {θ}_{steer} < \frac{λ}{π a} ) rad ;$$

for the seeding angle:

$$( arc sin [ m \frac{λ}{d} - sin ( \frac{λ}{π a} ) ] < {θ}_{seed} < arc sin [ m \frac{λ}{d} + sin ( \frac{λ}{π a} ) ] ) rad ;$$

and for a relationship between the steering angle and seeding angle: θₛₜₑₑᵣ<θ_{seed}; where λ is the wavelength of the seed beam and the one or more array beams, m is the diffraction order of the active grating (e.g., the seeded laser array), a is the diameter of individual VCSELs or PCSELs in the laser array, and d is the pitch or center-to-center distance of adjacent VCSELs or PCSELs in the laser array. In some embodiments of the laser system, the seeding angle is an angle at which maximum off-axis seeding efficiency is achieved based on (a) the mode match between the seed beam and the laser array and (b) the transmission of a top mirror in the laser array.

In some embodiments, a method is provided, comprising: propagating a seed beam emitted by a seed laser to an emitting side of a laser array comprising plurality of laser array emitters; and interfering the seed beam with one or more laser array beams emitted by one or more of the plurality of laser array emitters to lock the one or more array beams to a phase of the seed beam. In some embodiments of the method, propagating the seed beam to an emitting side of the laser array comprises: transmitting the seed beam to a reflector; and redirecting the seed beam to the emitting side of the laser array using the reflector. In some embodiments of the method, interfering the seed beam with a laser array beam emitted by a first laser array emitter of the plurality of laser array emitters comprises: receiving the seed beam with an optical routing element positioned on the emitting side of the laser array; and directing the seed beam to the first laser array emitter using the optical routing element. In some embodiments of the method, the method comprises changing a phase of the seed beam using one or more phase-changing elements prior to interfering the seed beam with at least one laser array beam of the one or more laser array beams. In some embodiments of the method, changing the phase of the seed beam using a phase-changing element of the one or more phase-changing elements comprises: transmitting the seed beam through the phase-changing element; and applying a voltage to the phase-changing element using a voltage source to cause a physical property of the phase-changing element to change, wherein the change in the physical property induces a change in the phase of the seed beam.

In some embodiments, a laser array steering system is provided, comprising: a laser array comprising a plurality of laser array emitters; a micro-lens array positioned on an emitting side of the laser array and comprising a plurality of micro-lenses; an actuator connected to and configured to adjust a position of the micro-lens array relative to the laser array; and one or more processors configured to control the actuator. In some embodiments of the laser array steering system, the actuator comprises a micro-electromechanical system. In some embodiments of the laser array steering system, the actuator comprises a translation stage. In some embodiments of the laser array steering system, the translation stage comprises a servo. In some embodiments of the laser array steering system, the translation stage comprises a piezoelectric device. In some embodiments of the laser array steering system, the one or more processors are configured to cause the actuator to adjust the position of the micro-lens array based on a location of a target and a separation distance between the micro-lens array and the laser array. In some embodiments of the laser array steering system, the system comprises one or more phase-changing elements positioned on an emitting side of the laser array and configured to induce phase changes in array beams emitted by one or more of the plurality of laser array emitters. In some embodiments of the laser array steering system, the one or more phase-changing elements comprise a material having a physical property that changes when a voltage is applied to the material, wherein the change in the physical property of the material induces a change in the phase of an array beam when the array beam propagates through the phase-changing element. In some embodiments of the laser array steering system, the one or more phase-changing elements are electro-optic modulators or piezoelectric devices. In some embodiments of the laser array steering system, the system comprises a voltage source electrically coupled to the one or more phase-changing elements. In some embodiments of the laser array steering system, the one or more processors are configured to control the voltage source. In some embodiments of the laser array steering system, the one or more processors are wirelessly coupled to the voltage source. In some embodiments of the laser array steering system, the plurality of laser array emitters comprise vertical-cavity surface-emitting lasers (VCSELs) or photonic crystal surface-emitting lasers (PCSELs).

In some embodiments, a method is provided, comprising: receiving one or more laser array beams emitted by one or more laser array emitters in a laser array at one or more micro-lenses of a micro-lens array positioned on an emitting side of the laser array; and adjusting a position of the micro-lens array relative to the laser array to steer the one or more laser array beams to a target location. In some embodiments of the method, adjusting the position of the micro-lens array relative to the laser array comprises transmitting a signal to an actuator connected to the micro-lens array using one or more processors. In some embodiments of the method, the signal causes the actuator to adjust the position of the micro-lens array based on a location of a target and a separation distance between the micro-lens array and the laser array. In some embodiments of the method, the method comprises changing a phase of a laser array beam of the one or more laser array beams using a phase-changing element. In some embodiments of the method, changing the phase of the laser array beam using the phase-changing element comprises: transmitting the laser array beam through the phase-changing element; and applying a voltage to the phase-changing element using a voltage source to cause a physical property of the phase-changing element to change, wherein the change in the physical property induces a change in the phase of the seed beam.

In some embodiments, a self-seeding laser system is provided, comprising: a laser array comprising a plurality of laser array emitters; and a diffraction grating; wherein the laser array is configured to emit one or more array beams that are incident on the diffraction grating, and the diffraction grating is configured to retroreflect a retroreflected seed beam in a first direction back onto the laser array and to reflect an output beam in a second direction towards a target, such that the retroreflected seed beam interferes with the one or more array beams and locks the one or more array beams to a phase of the retroreflected seed beam. In some embodiments of the self-seeding laser system, the system comprises an actuator configured to adjust a position of the diffraction grating to tune the system. In some embodiments of the self-seeding laser system, the system comprises: a mirror, wherein retroreflection of the retroreflected seed beam comprises reflection via a mirror; and an actuator configured to adjust a position of the mirror to tune the system.

In some embodiments, a method is provided, comprising: propagating one or more array beams from a laser array comprising a plurality of laser array emitters to a diffraction grating; propagating a retroreflected seed beam in a first direction back from the diffraction grating onto the laser array; and propagating an output beam in a second direction from the diffraction grating towards a target; wherein the retroreflected seed beam interferes with the one or more array beams and locks the one or more array beams to a phase of the retroreflected seed beam.

Any one or more of the above embodiments described above or elsewhere herein may be combined in whole or in part with one another and/or with any other feature or aspect described herein.

### BRIEF DESCRIPTION OF THE FIGURES

The following figures show various systems and methods for generating coherent emission from a laser array. The systems and methods shown in the figures may have any one or more of the characteristics described herein.

FIG. 1 shows a block diagram of a phase-locking laser array system, according to some embodiments.

FIG. 2 shows a first implementation of a phase-locking laser array system, according to some embodiments.

FIG. 3 shows a variation of the first implementation of the phase-locking laser array system, according to some embodiments.

FIG. 4 shows a variation of the first implementation of the phase-locking laser array system, according to some embodiments.

FIG. 5A shows a block diagram of a control system for a phase-changing element, according to some embodiments.

FIG. 5B shows a block diagram of a seed beam propagating through a phase-changing element, according to some embodiments.

FIG. 5C shows a block diagram of a seed beam propagating through a phase changing element in the presence of an applied voltage, according to some embodiments.

FIG. 6 shows a method of using the first implementation of the phase-locking laser array system, according to some embodiments.

FIG. 7A shows a second implementation of a phase-locking laser array system, according to some embodiments.

FIG. 7B shows an example plot of the seeding efficiency as a function of seed laser angle of incidence, according to some embodiments. In this example, 0-degree incidence angle is an ideal efficiency, but if an off-axis geometry is required, then seeding at 7.5 degrees is best.

FIG. 7C shows an embodiment of off-axis seeding. The seed laser is reflected off several optics before being received by the laser array, according to some embodiments.

FIG. 8 shows a close-up view of a laser array emitter in the second implementation of the phase-locking laser array system, according to some embodiments.

FIG. 9 shows a variation of the second implementation of the phase-locking laser array system, according to some embodiments.

FIG. 10 shows a variation of the second implementation of the phase-locking laser array system, according to some embodiments.

FIG. 11 shows a method of using the second implementation of the phase-locking laser array system, according to some embodiments.

FIG. 12 shows a block diagram of a beam steering system for a laser array, according to some embodiments.

FIG. 13 shows an implementation of a beam steering system, according to some embodiments.

FIG. 14 shows a second implementation of a beam steering system, according to some embodiments.

FIG. 15 shows a method of using a beam steering system for a laser array, according to some embodiments.

FIG. 16 shows a Littrow configuration of self-seeding a laser array using a diffraction grating, according to some embodiments.

FIG. 17. shows a Littman-Metcalf configuration of self-seeding a laser array using a diffraction grating and mirror, according to some embodiments.

### DETAILED DESCRIPTION

Optical power beaming—i.e., the wireless transmission of laser light from one location to another for constructive, destructive, or energy or power transfer purposes—has a wide range of potential use-cases. Systems which enable the transmission of substantial amounts of power without sacrificing portability and customizability are especially desirable in industries such as defense where the use of large, unadaptable, and inefficient systems are impractical or dangerous. Of particular interest are laser array systems, which have collections of individual laser emitters whose emissions can be combined to form a single, powerful beam. However, in order to use laser arrays to produce beams in power ranges larger than the kilowatt range, laser array systems require mechanisms that allow for the optical properties of large numbers of emitters to be precisely controlled.

Provided herein are laser array systems that produce highly coherent and controllable beams by locking each of the beams generated by individual laser emitters to the same phase. The phase to which each laser array element locks may be defined by the phase of a seed laser. Injecting the seed beam produced by the seed laser into each laser array element may force the array beams to match the seed laser's phase. Once the array beams are phase-locked, they may be combined with minimal destructive interference at the target, enabling large amounts of power to be efficiently transmitted from the laser array to a target.

The position of the seed laser relative to the laser array in the described systems may enable the systems to be manufactured and operated at low cost to the operator. Optical elements (e.g., phase-sensing and/or phase-changing elements) may be provided in varying numbers and spatial configurations relative to the two-dimensional laser array and may allow optical properties of the seed beam to be tailored to address specific regions of the laser array or, in some cases, individual laser array emitters in the laser array. This may increase the coherence of the beams emitted by each laser array element thereby increasing the overall efficiency and power output of the system.

In one configuration of the laser array system, the seed laser may be positioned in the same plane as the laser array. The seed beam may be directed to the laser array emitters by a waveguide that borders the laser array on one side. Deflectors embedded within the waveguide may allow the seed beam to be deflected to specific regions of the laser array (e.g., to specific rows of laser array emitters) without increasing the complexity of the waveguide itself (e.g., without requiring a curved or serpentine waveguide). Additional optical elements that facilitate highly localized control of the seed beam may also be provided.

In another configuration of the laser array system, the seed laser may be positioned on an emitting side of the laser array. This positioning may enhance the adaptability of the system, enabling its implementation in a variety of settings, particularly those with limited space or complex geometries. The positioning of the seed laser may also facilitate heat dissipation from the system when in use, reducing the need for expensive and bulky cooling equipment and lowering the risk of heat damage to the system components.

After the individual laser emitters in an array have been locked to a common phase, the (now coherent) array beams may require rapid steering in order to be efficiently transmitted to a target or receiver for constructive, destructive, or power beaming purposes. Accordingly, in addition to the phase-locking laser array systems described previously, a beam steering system for simultaneously controlling the directions and phases of beams emitted by elements of a laser array is described. The beam steering system may include a remotely controllable array of micro-lenses configured to be positioned on an emitting side of a laser array. When the laser array is in use, the position of the micro-lens array relative to the laser array may be adjusted in both directions parallel to the plane of the laser array in order to ensure that the power output from the laser array is maximized.

### Phase-Locking Systems

A laser array system for producing phase-locked beams can include a two-dimensional laser array and a seed laser. In various embodiments, the seed laser may be positioned in the same plane as, or on an emitting side of, the laser array, which may reduce manufacturing and operating costs associated with the system while increasing the system's efficiency, versatility, and configurability. Various additional optical elements, including waveguides, reflectors, and phase-changing elements, may be provided to enable certain positioning of the seed laser or to allow for localized optical control of specific regions of the laser array.

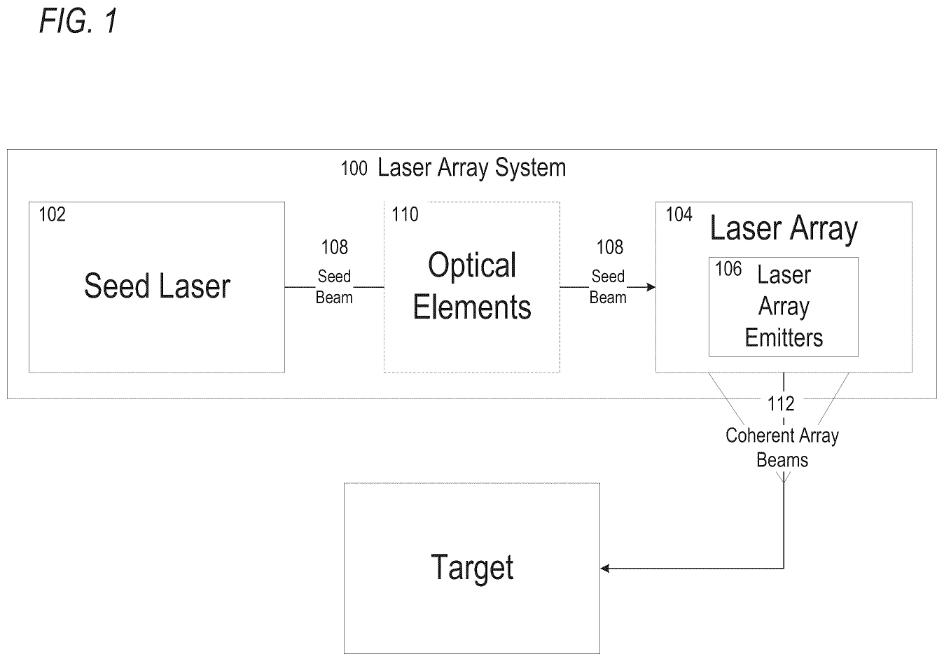

FIG. 1 depicts a block diagram of an exemplary laser array system 100. As shown, system 100 may comprise a seed laser 102 as well as a laser array 104 comprising a plurality of laser array emitters 106. Seed laser 102 may produce a seed beam 108 that may be propagated to laser array 104, where it may interfere with beams emitted by laser array emitters 106. As beam 108 interferes with the array beams, each array beam may lock to the optical phase of seed beam 108, producing a plurality of coherent array beams 112. Said coherent array beams 112 may then be constructively interfered with one another to generate a single beam of higher power than any individual array beam. This single, high-power beam can be transmitted to a desired target for constructive, destructive, or power-transfer purposes.

Seed laser 102 may be or may comprise any available laser type. For example, seed laser 102 may be or may comprise a gas laser (e.g., a carbon dioxide laser, a helium-neon laser, etc.), a chemical laser (e.g., a hydrogen fluoride laser, a deuterium fluoride laser, a chemical oxygen-iodine laser, etc.), a metal-vapor laser (e.g., a helium-cadmium laser, a copper vapor laser, etc.), a solid-state laser (e.g., a titanium-sapphire laser, an ytterbium-doped glass laser, etc.), a semiconductor laser diode, or any other type of laser.

Seed beam 108 may be in any electromagnetic wavelength range. In some embodiments, for instance, seed beam 108 has a wavelength in the ultraviolet range (e.g., a wavelength between about 100 nm and about 300 nm). In other embodiments, seed beam 108 has a wavelength in the visible range (e.g., a wavelength between approximately 400 nm and approximately 700 nm). In other embodiments, seed beam 108 has a wavelength in the infrared range (e.g., a wavelength between about 800 nm and about 1 mm).

In one or more examples, the power of seed beam 108 is greater than or equal to approximately 1 mW, 50 mW, 100 mW, 500 mW, 1 W, 50 W, 100 W, 500 W, or 1 kW. The power of seed beam 108 can also be less than or equal to approximately 500 kW, about 100 KW, approximately 50 kW, approximately 10 kW, approximately 1 kW, approximately 500 W, approximately 100 W, approximately 5 W, or approximately 1 W.

Laser array 104 may be a one-dimensional or two-dimensional array. Laser array emitters 106 can be arranged in any geometrical configuration. For example, laser array emitters 106 may be arranged in a linear, rectangular, ellipsoid, hexagonal, circular, or other geometrical configuration. In some embodiments, laser array 104 comprises at least 2, at least 3, at least 4, at least 5, at least 10, at least 15, at least 25, at least 50, at least 100, or at least 1000 laser array emitters 106.

Like seed laser 102, laser array emitters 106 can comprise any available laser types, including gas lasers (e.g., carbon dioxide lasers, carbon monoxide lasers, helium-neon lasers, etc.), chemical lasers (e.g., hydrogen fluoride lasers, deuterium fluoride lasers, chemical oxygen-iodine lasers, etc.), metal-vapor lasers (e.g., helium-cadmium lasers, copper vapor lasers, etc.), solid-state lasers (e.g., titanium-sapphire lasers, ytterbium-doped glass lasers, etc.), semiconductor laser diodes, or any combination thereof. In some embodiments, each laser array element 106 is a vertical-cavity surface-emitting laser (VCSEL) or a photonic crystal surface-emitting laser (PCSEL).

Depending on the geometry of laser array 104, the position of seed laser 102 with respect to laser array 104, and the optical properties of seed beam 108 and the array beams, seed beam 108 may be transmitted through one or more optical elements 110 prior to reaching laser array 104. Optical elements 110 may be photonic devices configured to change or control properties such as the phase, direction, or frequency of seed beam 108.

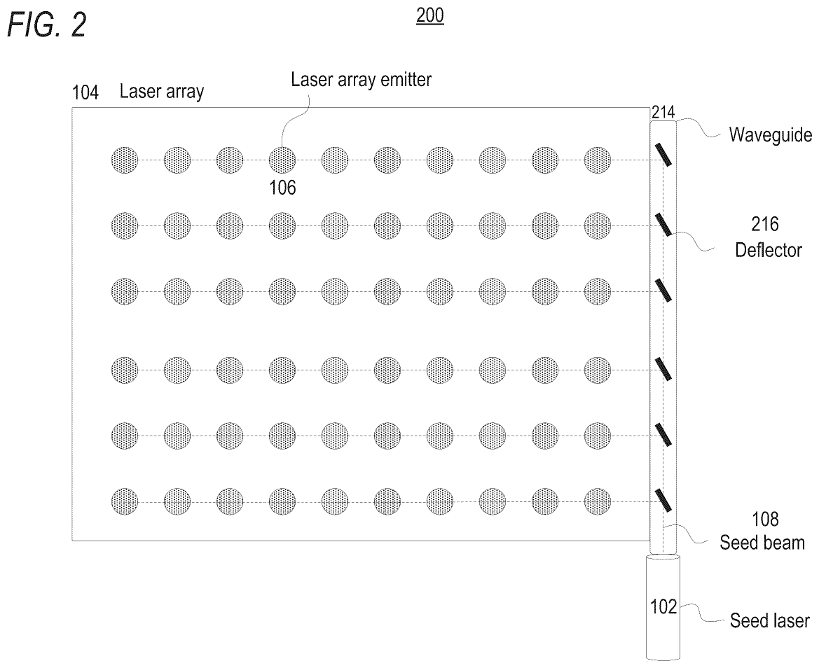

A perspective view of an example laser array system 200 is provided in FIG. 2. System 200 may be a possible implementation of laser array system 100 shown in FIG. 1. In system 200, seed laser 102 is positioned in the same plane as laser array 104. Positioning seed laser 102 in-plane with laser array 104 reduces the volume of the laser array system, potentially enabling the installation or use of system 200 in apparatuses or locations with limited space. The position of seed laser 102 may also facilitate the cooling of both seed laser 102 and laser array 104 while system 200 is in use by allowing heat to escape through the non-emitting side of laser array 104, reducing the risk of system damage due to overheating, and may also enable powering of the laser array via the non-emitting side.

To propagate seed beam 108 to laser array emitters 106, system 200 may comprise a waveguide 214 to transmit seed beam 108. In some embodiments, waveguide 214 is positioned along a border of laser array 104. In other embodiments, waveguide 214 is positioned within laser array 104, for example in the center of laser array 104. Positioning waveguide 214 within laser array 104 may enable the use of non-rectangular laser arrays (e.g., round laser arrays such as those produced using standard semiconductor wafer production processes) to implement laser array 104.

Waveguide 214 may be linear in shape and thus may be less costly to manufacture than waveguides that have curved or serpentine portions. The form of waveguide 214 may depend upon the intended use-case of system 200 as well as the particular laser types of seed laser 102 and laser array emitters 106. Example forms of waveguide 214 include a planar waveguide, a high-contrast waveguide, a sub-wavelength metasurface and metamaterial waveguide, a plasmonic waveguide, a dielectric waveguide, a plasmonic/dielectric hybrid waveguide, and an “on-chip” waveguide. Likewise, the material(s) that constitute waveguide 214 may depend upon the material(s) that make up seed laser 102 and laser array 104. Possible materials include, for example, aluminum gallium arsenide (AlGaAs) and silicon.

Embedded within waveguide 214 may be a plurality of partial-pass deflectors 216. As seed beam 108 propagates through waveguide 214, deflectors 216 may deflect seed beam 108 to various spatial regions of laser array 104. For example, if waveguide 214 is positioned along a border of laser array 104, and if laser array emitters 106 are arranged in rows or columns, each deflector 216 in waveguide 214 may be configured to deflect seed beam 108 to a particular row or column. If waveguide 214 is positioned within laser array 104 (e.g., in the center of laser array 104), each deflector 216 in waveguide 214 may deflect seed beam 108 left, right, or radially away from waveguide 214. Once deflected to a given spatial region of laser array 104, seed beam 108 may interfere with beams emitted by laser array emitters 106 in that spatial region.

In addition to deflectors 216, system 200 may include one or more phase-changing elements 318. Phase-changing elements 318 may be devices having physical properties that change in response to applied voltages. For example, phase-changing elements 318 may comprise electro-optic modulators (e.g., lithium niobate electro-optic modulators) or piezoelectric devices that change the phase of seed beam 108 by changing the length of the optical path of seed beam 108 (e.g., aluminum nitride piezo-optomechanical actuators; see Dong, M., Clark, G., Leenheer, A. J. et al. High-speed programmable photonic circuits in a cryogenically compatible, visible-near-infrared 200 mm CMOS architecture. Nat. Photon. 16, 59-65 (2022)). Applying an appropriate voltage to a phase-changing element 318 through which seed beam 108 is propagating may alter a physical property of the phase-changing element 318 which may, in turn, induce a phase shift in seed beam 108.

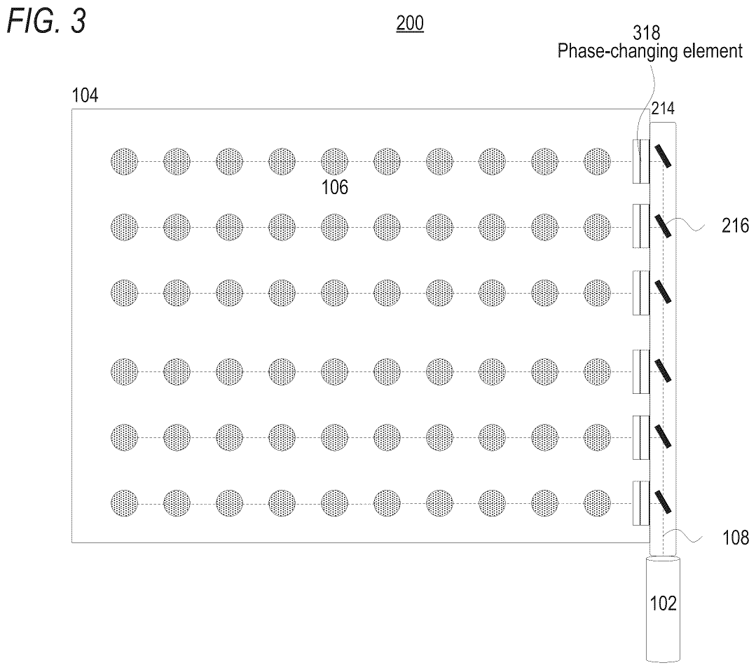

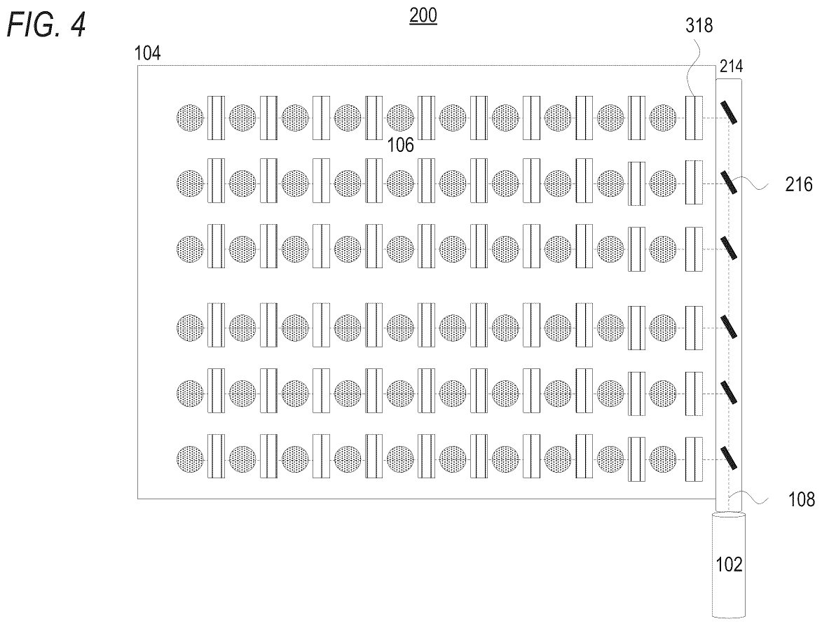

Phase-changing elements 318 may be positioned in an optical path of seed beam 108 at various locations on laser array 104. In one example, as shown in FIG. 3, a phase changing element 318 positioned “downstream” (relative to the propagation direction of seed beam 108) of each deflector 216. Seed beam 108 may pass through a phase-changing element 318 after being deflected by a deflector 216 to a particular spatial region of laser array 104. In another example, as shown in FIG. 4, a phase-changing element 318 positioned “upstream” (relative to the propagation direction of seed beam 108) and adjacent to each laser array element 106 so that seed beam 108 passes through a phase-changing element 318 before interfering with each laser array beam. It may be advantageous to phase-lock different regions of laser array 104 to different phases. This can be accomplished by positioning phase-changing elements 318 at different locations relative to laser array emitters 106 (i.e., phase-changing elements 318 may be translated in a plane perpendicular to the optical propagation path of laser array 104).

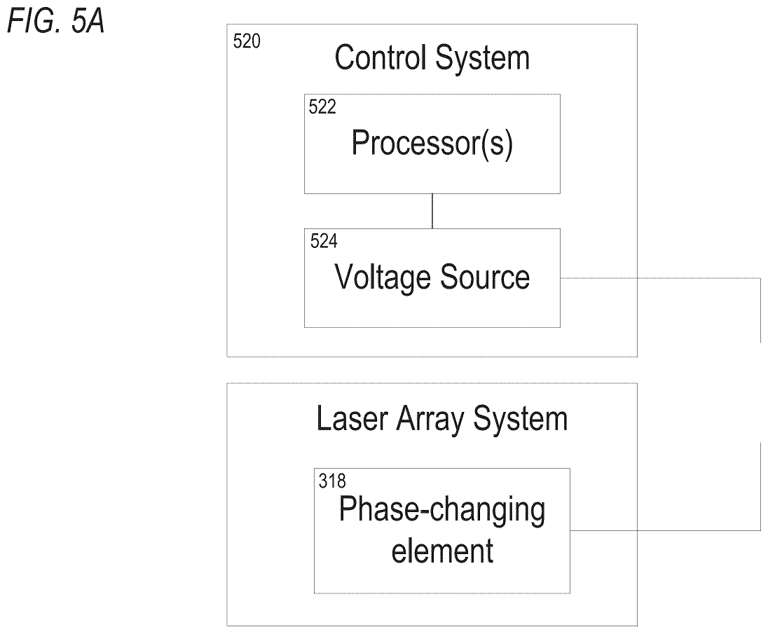

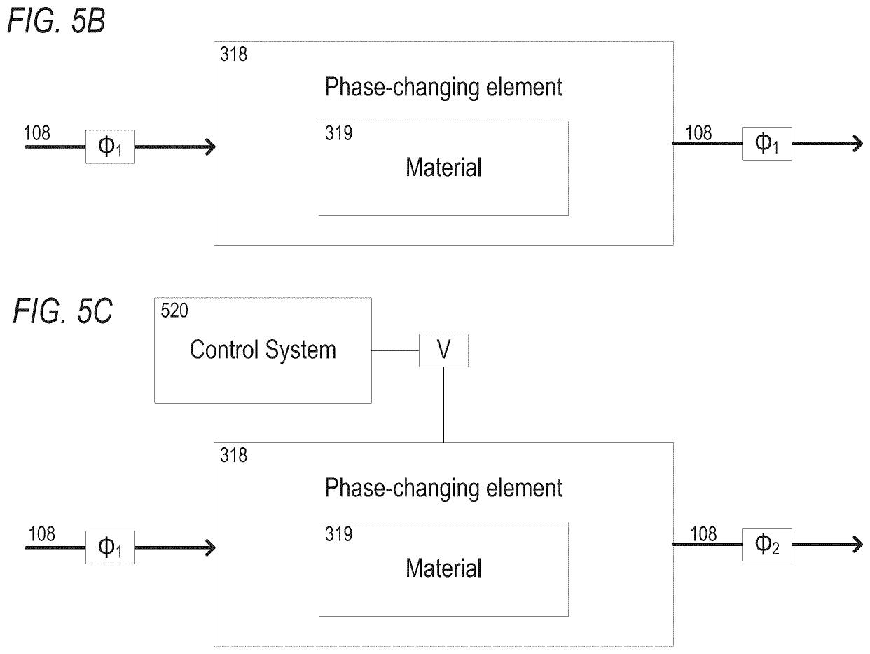

FIG. 5A provides a block diagram of an exemplary control system 520 for controlling a phase-changing element 318. As shown, control system 520 may comprise one or more processors 522 as well as a voltage source 524. Processor(s) 522 may be communicatively coupled to and configured to control voltage source 524. The coupling between processor(s) 522 and voltage source 524 may be wireless, enabling voltage source 524—and, as a result, phase-changing element 318—to be remotely controlled. Voltage source 524 may be electrically coupled to a phase-changing element 318 in the laser array system, for example by a wired connection or, if the laser array system is implemented on a chip, by conductive traces on the chip. In some embodiments, phase-changing element 318 can be configured by a user. The user may provide information indicating, e.g., a voltage to be supplied by voltage source 524 or an amount by which the phase of the seed beam should be shifted by phase-changing element 318, to processor(s) 522 using, for example, a user interface (e.g., a display), user controls (e.g., a keyboard, an adjustable knob, a button, etc.), or a combination thereof. In some embodiments, processor(s) 522 may be configured to execute software containing instructions for automatically determining an appropriate amount of voltage to apply to phase-changing element 318 based on, e.g., the desired and sensed phase of an array beam emitted by an array element in the laser array.

FIGS. 5B-5C illustrate the structure of an exemplary phase-changing element 318. As previously noted, phase-changing element 318 may comprise a material 319 that has a physical property that changes when a voltage is applied to material 319 (e.g., by a control system 520). If, for example, phase-changing element 318 is an electro-optic modulator, material 319 may be a nonlinear optical material with a refractive index and absorption that change in the presence of an applied voltage (due to the electro-optic effect). Similarly, if phase-changing element 319 is a piezoelectric device, material 319 may be a piezoelectric material that expands or contracts in the presence of an applied voltage and electric field (due to the piezoelectric effect). When no voltage is applied to material 319 while seed beam is propagating through phase-changing element 318, as shown in FIG. 5B, the physical properties of material 319 may remain constant, and, as a result, the phase of seed beam 108 may not change (e.g., seed beam 108 may have the same phase φ₁ prior to passing through phase-changing element 318 as it has after exiting phase-changing element 318). However, when a voltage is applied to material 319 while seed beam 108 is propagating through phase-changing element 318, as shown in FIG. 5C, the change in the physical property of material 319 may induce a change in the phase (e.g., from a first phase φ₁ to a second phase φ₂) of seed beam 108.

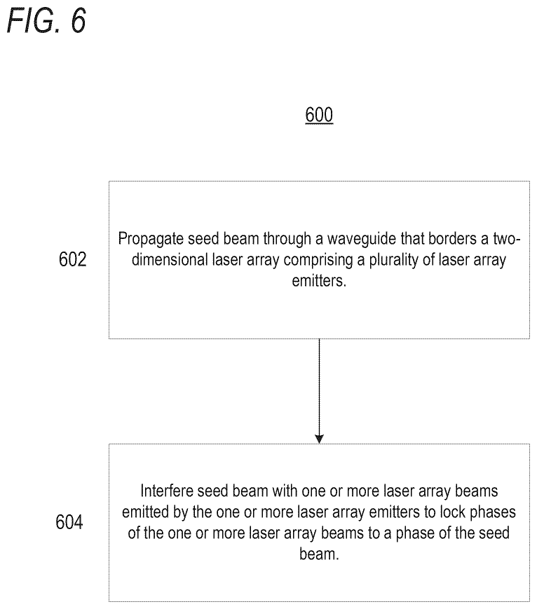

A method 600 of using a laser array system with a seed laser positioned in the same plane as the laser array (e.g., system 200 shown in FIGS. 2-4) is provided in FIG. 6. To produce coherent emission from the laser array, a seed beam generated by the seed laser may be propagated through a waveguide that borders the laser array (step 602). The seed beam may be directed to a particular spatial region of the laser array or to a particular laser array element by partial-pass deflectors embedded in the waveguide. Subsequently, the seed beam may be caused to interfere with one or more laser array beams emitted by one or more of the laser array emitters in the laser array in order to lock the phases of the laser array beams to a phase of the seed beam (step 604). Optionally, the phase of the seed beam may be adjusted using phase-changing elements before the seed beam is transmitted to a particular spatial region of the laser array or to a particular laser array element in order to lock the spatial region of the laser array or the laser array element to a unique phase.

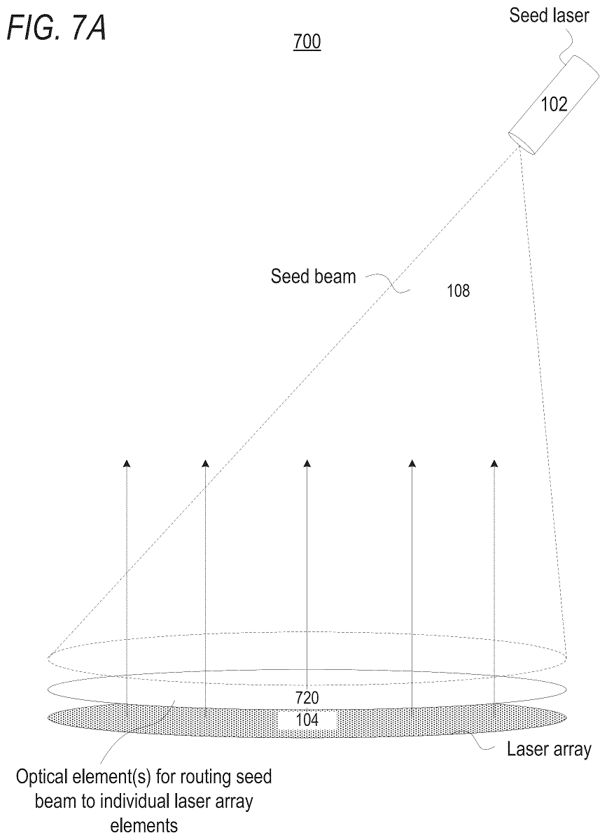

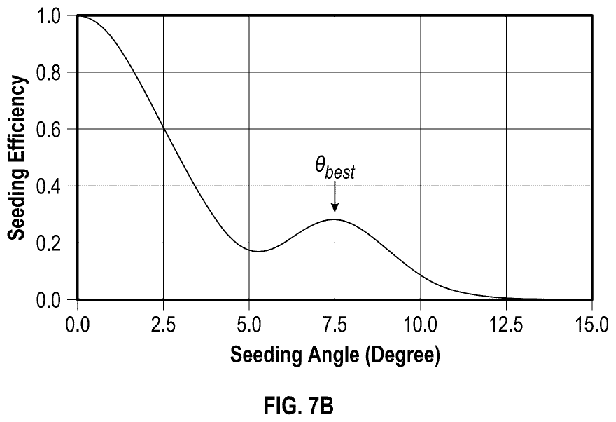

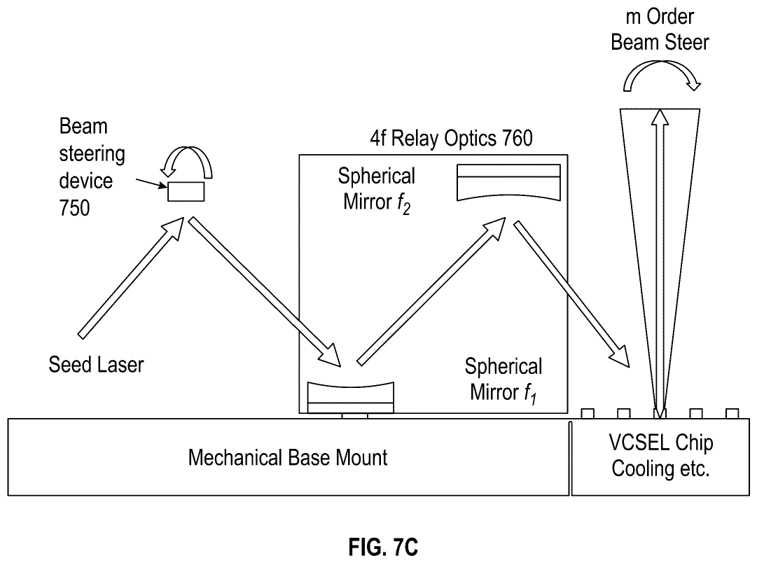

FIG. 7A depicts a perspective view of a second example laser array system 700. Like system 200 (FIGS. 2-4), system 700 may be a possible implementation of laser array system 100 (FIG. 1). In system 700, seed laser 102 may be positioned on an emitting side of laser array 104. Seed laser 102 may be placed at any location on an emitting side of laser array 104, enabling system 700 to be adapted for a wide variety of use-cases. Additionally, the position of seed laser 102 may allow heat generated by laser array 104 during use to be emitted through the non-emitting side of laser array 104, facilitating cooling of system 700.

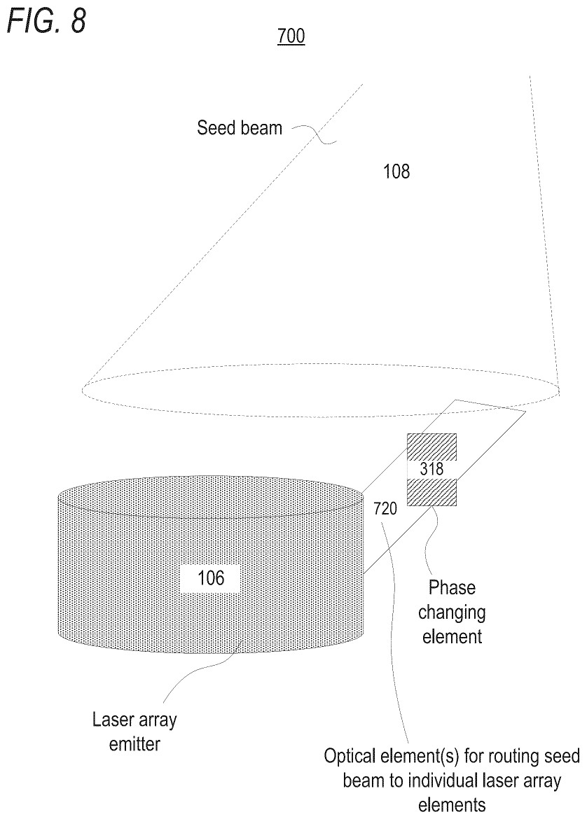

System 700 may include optical routing elements 720 positioned on an emitting side of laser array 104 that are configured to route seed beam 108 to particular spatial regions of laser array 104 or to individual laser array emitters in laser array 104. Optical routing elements 720 may comprise lenses (e.g., micro-lenses), waveguides, diffraction gratings, or a combination thereof. (While optical routing elements 720 are schematically represented in FIG. 7A as a single disc, it is to be understood based on the disclosure herein that optical routing elements 720 may comprise a plurality of separate, distinct, discrete routing elements such as lenses (e.g., micro-lenses), waveguides, diffraction gratings, or a combination thereof.) Optical routing elements 720 may further comprise a metamaterial lattice interposed between individual laser array emitters in laser array 104. In addition, like system 200 shown in FIGS. 2-4, system 700 may include one or more phase-changing elements (e.g., electro-optic modulators or piezoelectric devices, as previously described with respect to FIGS. 3-4). As shown in FIG. 8, a phase-changing element 318 may be associated with a particular laser array element 106, enabling the phase of seed beam 108 to be uniquely adjusted to target each individual laser array element 106. Phase-changing element 318 may be controlled by a control system such as system 520 shown in FIG. 5.

In some embodiments, the ability of the seed beam to seed the laser array is governed by a Maximum Seeding Efficiency. Maximum seeding efficiency is typically achieved when the external seeding laser seeds the laser array in the direction of the surface normal of the laser array (so-called on-axis seeding). Seeding efficiency usually drops rapidly as the angle between the seeding laser and the surface normal of the laser array increases (so-called off-axis seeding). However, a laser array may be configured such that a preferable off-axis seeding angle exists (for example, θ_{best}=7.5° as shown in embodiment depicted in FIG. 7B). Configurations in which a preferable off-axis seeding angle exists may make off-axis seeding feasible. This preferable off-axis seeding is a result of the trade-off between the decreasing of the mode match between the seeding laser and the laser array and the increasing transmission of the top mirror in laser array. The preferable off-axis seeding angle can be designed by changing the mode match and the top mirror reflectivity of laser.

Off-axis seeding may be preferred in some cases with the following two characteristics: (1) the seeding laser beam is well separated from the laser beams of the laser array. This separation may avoid (or minimize) beam truncation of the laser array by the seeding laser optics; (2) enable beam steering of the laser array, which can be achieved from changing the angle of the seeding laser. The following equations can be used to provide off-axis seeding that meets the above two characteristics.

$$Steering angle : ( - \frac{λ}{π a} < {θ}_{steer} < \frac{λ}{π a} ) rad \qquad ( 1 )$$

$$Seeding angle : \\ ( arc sin [ m \frac{λ}{d} - sin ( \frac{λ}{π a} ) ] < {θ}_{seed} < arc sin [ m \frac{λ}{d} + sin ( \frac{λ}{π a} ) ] ) rad \qquad ( 2 )$$

$$Constraints : {θ}_{steer} < {θ}_{seed} \approx {θ}_{best} \qquad ( 3 )$$

In the equations above, A is the wavelength of the seed beam and the one or more array beams, m is the diffraction order of the active grating (e.g., the seeded laser array), a is the diameter of individual VCSELs or PCSELs in the laser array, and d is the pitch or center-to-center distance of adjacent VCSELs or PCSELs in the laser array.

Equation (1) determines the maximum steerable angle of a laser array. Equation (2) determines how the beam direction of laser array 104 changes with the seeding laser angle. Equation (3) guarantees that there is no beam overlap between the seeding laser and the laser array. In this configuration, the laser array 104 behaves as an active grating when seeded with the seeding laser under the off-axis seeding condition. The laser beam emitting direction from laser array will follow the angle change of the seeding laser according to the grating equation. For example, for a laser array that has a pitch of 20 μm and an individual laser aperture size of 10 μm, its maximum steering angle is in the range from −1.8° to 1.8° when choosing the diffraction order m=3 and its corresponding seeding angle is in the range from 6.7° to 10°. The off-axis seeding laser and the laser beam from laser array are well separated in this scenario.

In some embodiments, angle change of the seeding laser can be achieved by using beam steering, for example as shown in FIG. 7C. In the example shown, a beam steering device 750 directs a seed laser beam into 4f relay optics 760, the 4f relay optics 760 comprising two spherical mirrors that are used for (1) expanding the seeding laser beam size from the beam steering element to match the size of the laser array and (2) keeping the alignment of the seeding laser and laser array unchanged when changing the seeding angle. A wide variety of beam steering speeds can be achieved by choosing the right beam steering device. This beam steering device may comprise any one or more of the following components: (1) a piezoelectric steering mirror with coatings optimized to the workable wavelength of the system that can steer the beam, for example, at the speed of 2 kHz; (2) MEMS mirrors that can steer the beam, for example, at a speed ranging from 0.3 to 6 kHz; (3) piezo-tube that can steer the beam at a speed, for example, ranging from 1 kHz to 10 MHz.

System 700 can also include optical elements configured to adjust an intensity, an angle, or a frequency of seed beam 108 as it propagates to a laser array element 106. These optical elements may include electrooptic modulators, electroacoustic modulators, deformable mirror devices, and blazed gratings. These optical elements may be positioned similarly to phase-changing element 318 shown in FIG. 8.

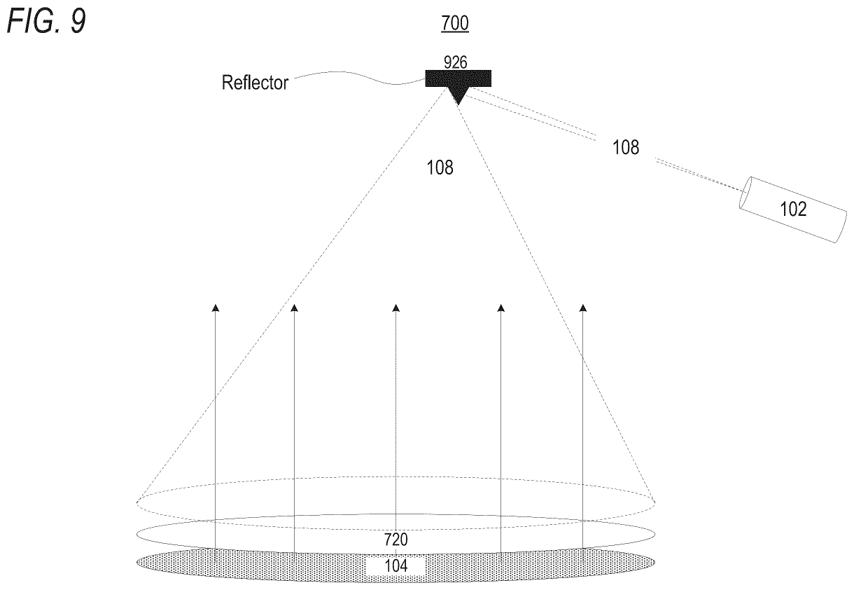

To prevent damage to seed laser 102 by the laser array beams emitted by laser array emitters 106, seed laser 102 may be offset from the optical paths of the array beams. Specifically, seed laser 102 may be positioned such that it resides off angle from the direction of propagation of the array beams produced by laser array 104. In some embodiments, as shown in FIG. 7A, seed laser 102 is offset from laser array 104 and positioned such that seed beam 108 propagates directly from seed laser 102 to the emitting side of laser array 104. In other embodiments, seed laser 102 may be positioned such that seed beam 108 is not directed to the emitting side of laser array 104. For instance, as shown in FIG. 9, seed laser 102 may be offset from laser array 104 and angled such that seed beam 108 propagates transversely to laser array 104. To facilitate interference between seed beam 108 and the laser array beams, system 100 may include a reflector 926 that is configured to redirect seed beam 108 to the emitting side of laser array 104. Reflector 926 may consist of a parabolic mirror, a beam expander, or a flat mirror.

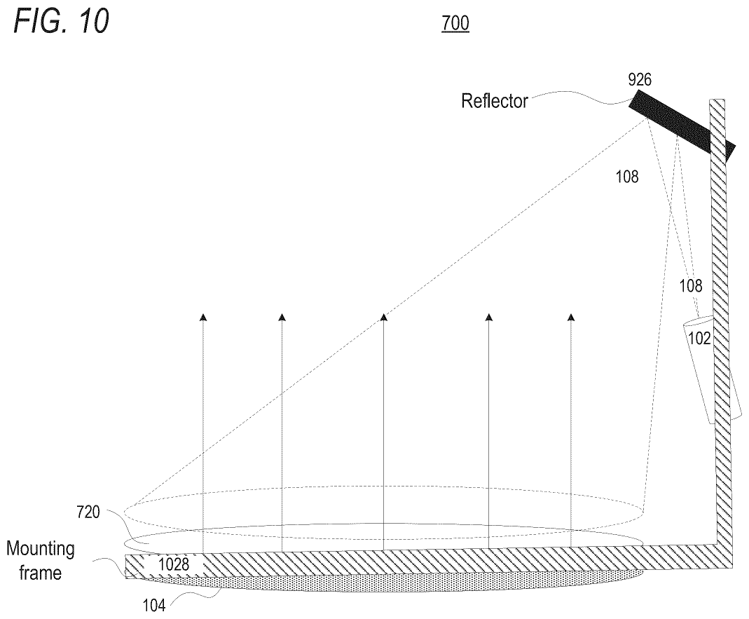

In some embodiments, as illustrated in FIG. 10, the position of seed laser 102, along with any optical elements (e.g., reflector 822) configured to control the direction of seed beam 108, is fixed by a mounting frame 1028. Seed laser 102 and any necessary optical elements may be attached to frame 1028, for example by fasteners (e.g., screws, bolts, pins, etc.), adhesive (e.g., epoxy, glue, etc.), or solder. Optionally, seed laser 102 may be configured to be movable between a plurality of positions along frame 1028 so that system 700 may be adapted for use in different settings.

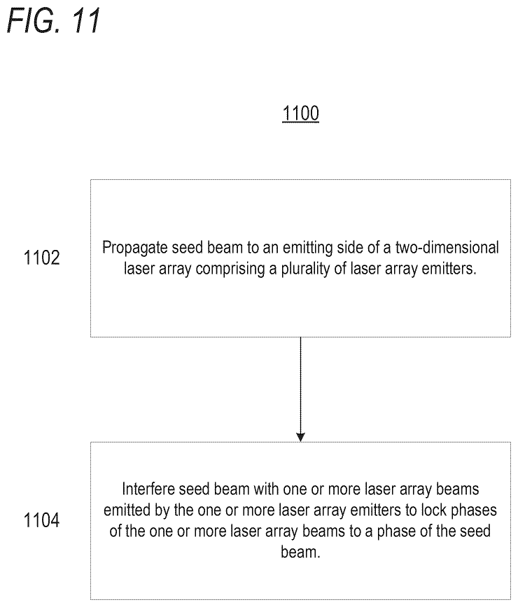

A method 1100 of using a laser array system with a seed laser positioned on an emitting side of the laser array (e.g., system 700 shown in FIGS. 7-10) is provided in FIG. 11. To produce coherent emission from the laser array, a seed beam generated by the seed laser may be propagated to the emitting side of the laser array (step 1102). The optical path of seed beam may, in some cases, be adjusted by one or more reflectors, depending on the position of the seed laser with respect to the laser array. The seed beam may be directed to a particular spatial region of the laser array or to a particular laser array element by optical routing elements (e.g., diffraction gratings or micro-lenses) positioned on an emitting side of the laser array. Subsequently, the seed beam may be caused to interfere with one or more laser array beams emitted by one or more of the laser array emitters in the laser array in order to lock the phases of the laser array beams to a phase of the seed beam (step 1104). Optionally, the phase of the seed beam may be adjusted using phase-changing elements before the seed beam is transmitted to a particular spatial region of the laser array or to a particular laser array element in order to lock the spatial region of the laser array or the laser array element to a unique phase.

### Beam Steering Systems

The various embodiments of laser array system 100 (e.g., system 200 shown in FIGS. 2-4 and system 700 shown in FIGS. 7-10) may be used to lock the phases of beams emitted by different emitters in a laser array to a single, common phase. Once the array beams have been phase-locked, they may be transmitted to a target for constructive, destructive, or power beaming purposes, as illustrated in FIG. 1. The beam steering systems described herein may be used to efficiently steer the phase-locked array beams to a desired target.

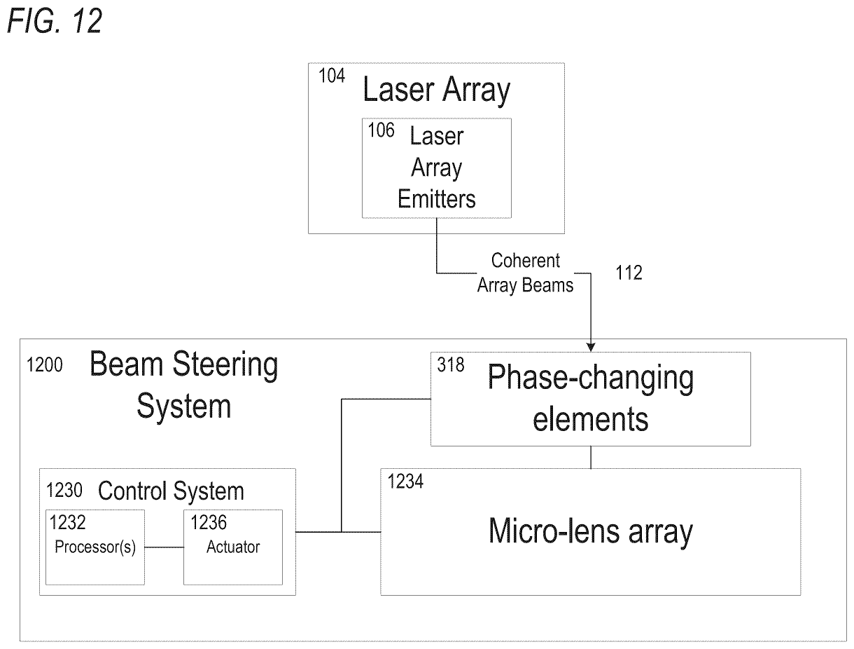

FIG. 12 depicts a block diagram of an exemplary beam steering system 1200. As shown, system 1200 may comprise a micro-lens array 1234. Micro-lens array 1234 may be positioned on an emitting side of laser array 104 in the optical paths of coherent array beams 112 and may include a micro-lens corresponding to each laser array element 106 in laser array 104. The position of micro-lens array 1234 with respect to laser array 104 may be adjustable in one or more dimensions by a control system 1230. When coherent array beams 112 from laser array 104 pass through micro-lens array 1234 and the position of micro-lens array 1234 with respect to laser array 104 is adjusted, the propagation directions of coherent array beams 112 may change, enabling the steering of coherent array beams 112 to a desired target location.

Control system 1230 may comprise an electrical actuation system 1236 configured to displace micro-lens array 1234 in response to applied electric signals. In some examples, actuator 1236 can comprise a micro-electromechanical system (MEMS) that is configured to shift the position of micro-lens array 1234. In other examples, actuator 1236 can include a translation stage upon which micro-lens array 1234 may be mounted. The translation stage may comprise a piezoelectric device or a servo and may be configured to move in one or more dimensions with respect to laser array 104 in response to applied electronic signals.

The amount and direction in which micro-lens 1234 is moved may be controlled by one or more processors 1232 in control system 1230. Processor(s) 1230 may be configured to determine an amount and direction in which micro-lens array 1234 should be moved in order to steer beams 112 to a target based on the location of the target with respect to an initial propagation direction of beams 112 as beams 112 travel through micro-lens array 1234 as well as a separation distance between laser array 104 and micro-lens array 1234. In some embodiments, the location of the target and the separation distance between laser array 104 and micro-lens array 1234 may be provided to processor(s) 1230 by a user (e.g., via a user interface).

In some situations, there may be variations in the phases of coherent array beams 112, even after the beams have been phase-locked to a common phase by a laser array system such as system 100. To compensate for such variations, beam steering system 1200 can include phase-changing elements 318 (e.g., electro-optic modulators or piezoelectric devices, as previously described with respect to FIGS. 3-4) configured to modulate the phases of coherent array beams 112. In particular, system 1200 may comprise phase-changing elements 318 configured to independently control the phases of each coherent array beam 112. This additional phase tuning stage may increase the coherence of array beams 112 and, as a result, decrease energy loss at the target location due to destructive interference. Control system 1230 may comprise components similar to control system 520 shown in FIG. 5 for controlling phase-changing elements 318.

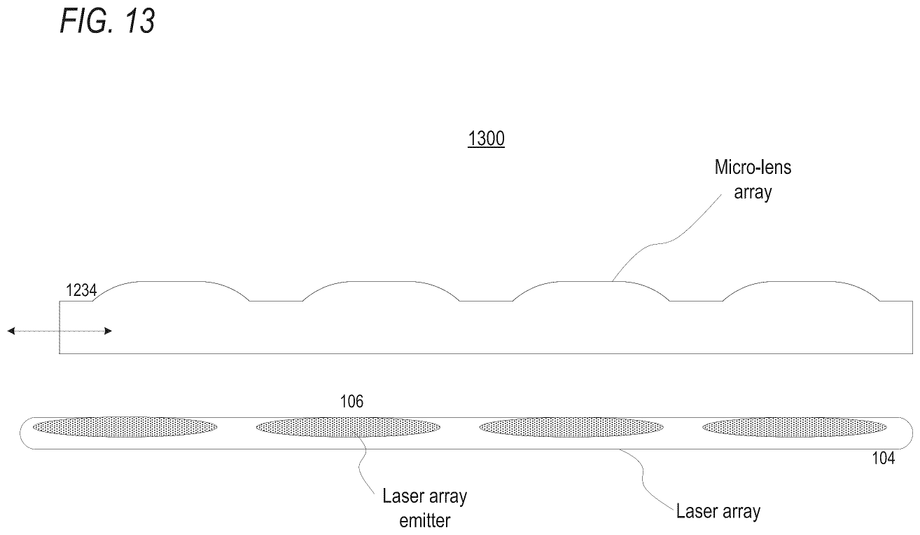

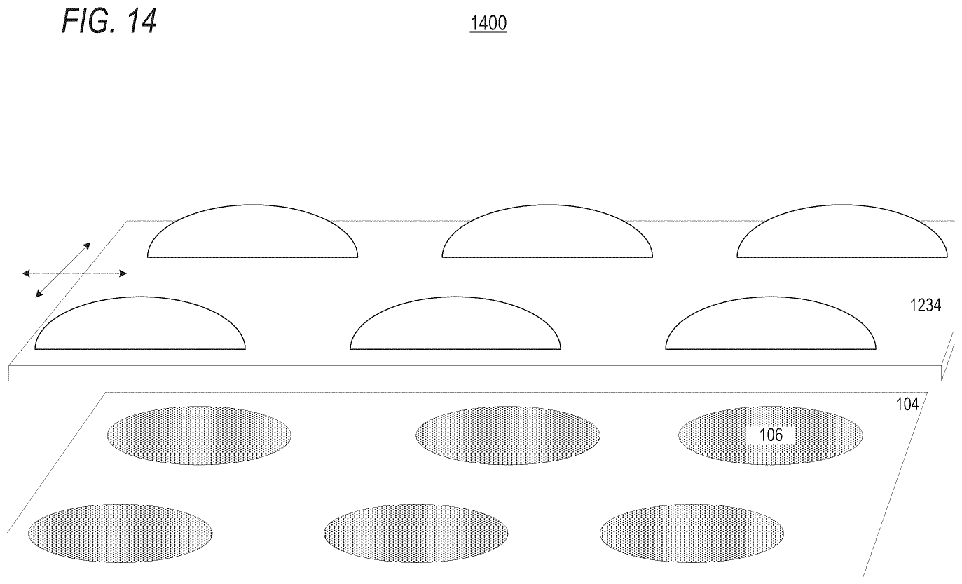

FIGS. 13-14 depict perspective views of a one-dimensional beam steering system 1300 (FIG. 13) and a two-dimensional beam steering system 1400 (FIG. 14). Systems 1300 and 1400 may be possible implementations of beam steering system 1200 shown in FIG. 12. System 1300 may comprise a one-dimensional (e.g., linear) micro-lens array 1234 that is configured to move back and forth along a line that is parallel to laser array 104. System 1400 may comprise a two-dimensional (e.g., circular, rectangular, etc.) micro-lens array 1234 that is configured to move within a plane that is parallel to laser array 104. Both system 1300 and system 1400 may include a control system such as system 1230 (FIG. 12) for controlling the positions of their respective micro-lens arrays. Additionally, both system 1300 and system 1400 may include phase-changing elements for tuning the phases of beams from laser array emitters 106, as shown in FIG. 12.

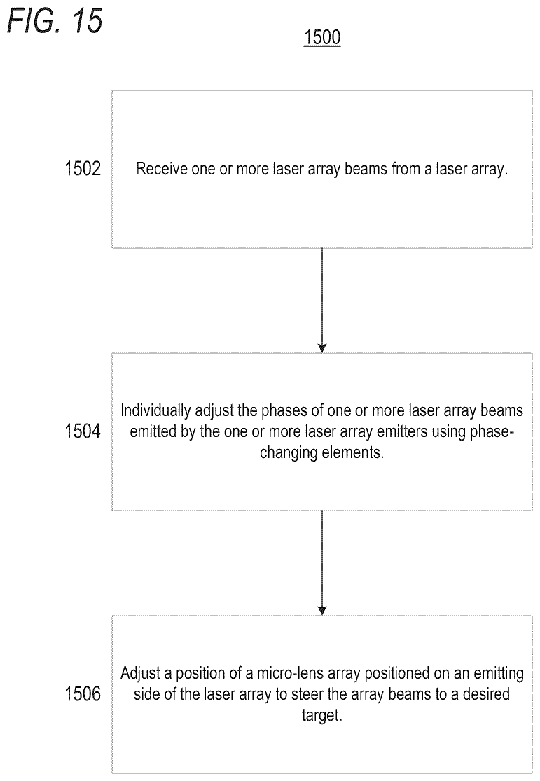

A method 1500 for using a beam steering system such as system 1300 is provided in FIG. 15. Laser array beams emitted by individual laser array emitters in a laser array may be received by the beam steering system (step 1502). The phases of these array beams may be independently tuned by phase-changing elements, for example to drive each array beam as close to a common phase as possible (step 1504). Tuning the phase of an array beam may involve applying a voltage to an appropriate phase-changing element in order to induce a change in a physical property of said phase-changing element that, in turn, induces a phase shift in the array beam as the array beam propagates through the phase-changing element. Each array beam may then be transmitted through a micro-lens in a micro-lens array. The array beams may be steered to a common target location by adjusting the position of the micro-lens array with respect to the laser array may be adjusted, for instance using a MEMS or a translation stage comprising a servo or a piezoelectric device (step 1506). The amount and direction in which the micro-lens array is moved in order to steer the array beams to the target location may be determined by one or more processors based on the location of the target with respect to an initial propagation direction of the beams as the beams travel through the micro-lens array as well as a separation distance between the laser array and the micro-lens array.

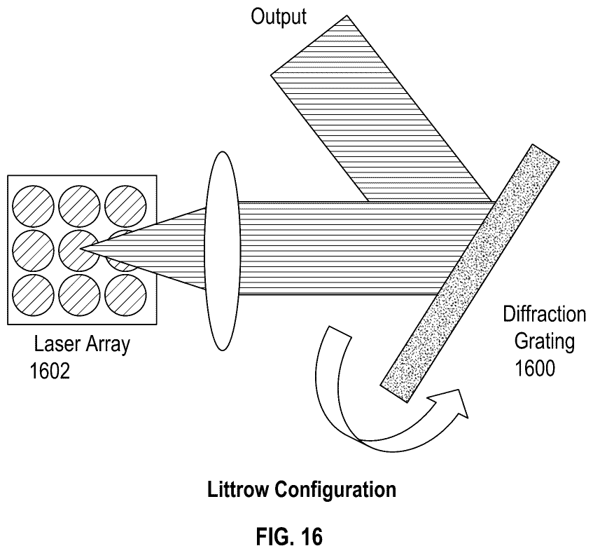

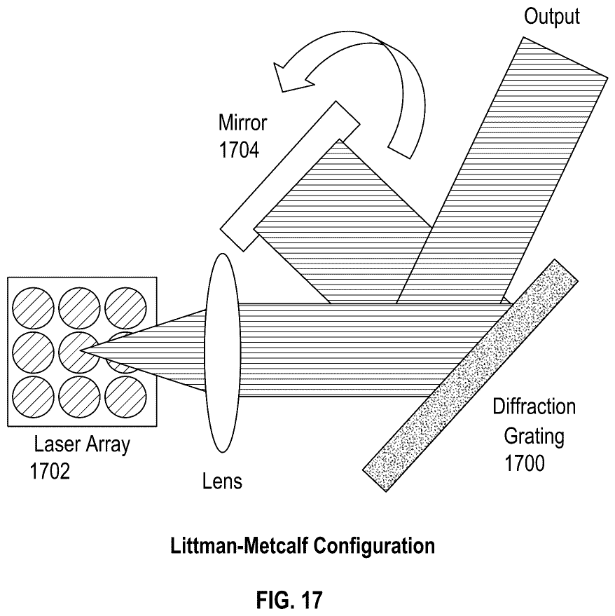

In some embodiments, as shown for example in FIGS. 16 and 17, a self-seeding approach may be used, in which the laser array beams are received by a diffraction grating (1600 or 1700). For example, a Littrow configuration (as shown, for example, in FIG. 16) and/or Littman-Metcalf configuration (as shown, for example, in FIG. 17) may be used. In these embodiments, one reflection off the grating (1600 or 1700) may be retro-reflected back onto the laser array (1602 or 1702), and another reflection off the grating may be transmitted to the target. The retro-reflected beam off the grating may serve as the seed beam. Mechanical adjustment of the grating in the Littrow configuration and/or mechanical adjustment of the mirror 1704 in the Littman-Metcalf configuration may tune the seed beam wavelength. Tuning of the seed beam in this manner may be used to match the free-running wavelength of the laser array. An advantage of these embodiments is that the laser array is self-seeding. Thus, no external laser is required. Another advantage of these embodiments is that the output beam to the target can be steered by mechanically adjusting the mirror and/or grating.

Below is a listing of exemplary embodiments:
1. A laser system comprising:
   a laser array comprising a plurality of laser array emitters;
   a seed laser; and
   a waveguide bordering the laser array and configured to optically couple the seed laser to the plurality of laser array emitters,
   wherein the seed laser is configured to emit a seed beam that interferes with one or more array beams emitted by the one or more of the plurality of laser array emitters and locks the one or more array beams to a phase of the seed beam.
2. The system of embodiment 1, wherein the waveguide is linear in shape.
3. The system of embodiment 1 or 2, wherein the laser array is a two-dimensional laser array.
4. The system of any one of embodiments 1-3, wherein the waveguide comprises one or more partial pass deflectors configured to deflect the seed beam to one or more spatial regions of the laser array.
5. The system of any one of embodiments 1-4, comprising one or more phase-changing elements positioned in an optical path of the seed laser and configured to change the phase of the seed beam.
6. The system of embodiment 5, wherein each phase-changing element of the one or more phase-changing elements is positioned next to a laser array emitter of the plurality of laser array emitters.
7. The system of embodiment 5 or 6, wherein the one or more phase-changing elements comprise a material having a physical property that changes when a voltage is applied to the material, wherein the change in the physical property of the material induces a change in the phase of the seed beam when the seed beam propagates through the phase-changing element.
8. The system of embodiment 7, wherein the one or more phase-changing elements are electro-optic modulators or piezoelectric devices.
9. The system of any one of embodiments 5-8, comprising:
   a voltage source electrically coupled to the one or more phase changing elements; and
   one or more processors configured to control the voltage source.
10. The system of embodiment 9, wherein the one or more processors are wirelessly coupled to the voltage source.
11. The system of any one of embodiments 1-10, wherein the plurality of laser array emitters comprise vertical-cavity surface-emitting lasers (VCSELs) or photonic crystal surface-emitting lasers (PCSELs).
12. The system of any one of embodiments 1-11, wherein the waveguide comprises aluminum gallium arsenide.
13. A method comprising:
   propagating a seed beam emitted by a seed laser through a waveguide bordering a laser array comprising a plurality of laser array emitters; and
   interfering the seed beam with one or more laser array beams emitted by one or more of the plurality of laser array emitters to lock the one or more laser array beams to a phase of the seed beam.
14. The method of embodiment 13, comprising deflecting the seed beam to one or more spatial regions of the laser array using one or more partial-pass deflectors embedded in the waveguide.
15. The method of embodiment 13 or 14, comprising changing a phase of the seed beam using one or more phase-changing elements prior to interfering the seed beam with at least one laser array beam of the one or more laser array beams.
16. The method of embodiment 15, wherein changing the phase of the seed beam using a phase-changing element of the one or more phase-changing elements comprises:
   transmitting the seed beam through the phase-changing element; and
   applying a voltage to the phase-changing element using a voltage source to cause a physical property of the phase-changing element to change, wherein the change in the physical property induces a change in the phase of the seed beam.
17. A laser system comprising:
   a laser array comprising a plurality of laser array emitters; and
   a seed laser positioned on an emitting side of the laser array;
   wherein the seed laser is configured to emit a seed beam that interferes with one or more array beams emitted by the one or more of the plurality of laser array emitters and locks the one or more array beams to a phase of the seed beam.
18. The system of embodiment 17, wherein a position of the seed laser is offset from optical paths of the one or more array beams.
19. The system of embodiment 17 or 18, wherein the seed laser is directed away from the emitting side of the laser array, and the system comprises one or more reflectors configured to redirect the seed beam to the emitting side of the laser array.
20. The system of any one of embodiments 17-19, comprising an optical routing element positioned on the emitting side of the laser array and configured to direct the seed beam to a first laser array emitter of the plurality of laser array emitters.
21. The system of embodiment 20, wherein the optical routing element is a diffraction grating.
22. The system of embodiment 20, wherein the optical routing element is a micro-lens.
23. The system of any one of embodiments 17-22, comprising one or more phase-changing elements positioned on an emitting side of the laser array and configured to change the phase of the seed beam.
24 The system of embodiment 23, wherein the one or more phase-changing elements comprise a material having a physical property that changes when a voltage is applied to the material, wherein the change in the physical property of the material induces a change in the phase of the seed beam when the seed beam propagates through the phase-changing element.
25. The system of embodiment 24, wherein the one or more phase-changing elements are electro-optic modulators or piezoelectric devices.
26. The system of any one of embodiments 23-25, comprising:
   a voltage source electrically coupled to the one or more phase changing elements; and
   one or more processors configured to control the voltage source.
27. The system of embodiment 26, wherein the one or more processors are wirelessly coupled to the voltage source.
28. The system of any one of embodiments 17-27, comprising a frame, wherein the seed laser is attached to the frame.
29 The system of embodiment 28, wherein the seed laser is movable between a plurality of positions along the frame.
30 The system of any one of embodiments 17-29, wherein the laser array emitters comprise vertical-cavity surface-emitting lasers (VCSELs) or photonic crystal surface-emitting lasers (PCSELs).
31. The system of any one of embodiments 17-30, wherein the laser array is a two-dimensional laser array.
32. The system of any one of embodiments 17-31, wherein the seed beam forms a seeding angle θ_{seed} of incidence with respect to the laser array, the one or more array beams form a steering angle θₛₜₑₑᵣ with respect to the laser array, and the steering angle and seeding angle comply with the following:
   for the steering angle:

$$( - \frac{λ}{π a} < {θ}_{steer} < \frac{λ}{π a} ) rad ;$$

for the seeding angle:

$$( arc sin [ m \frac{λ}{d} - sin ( \frac{λ}{π a} ) ] < {θ}_{seed} < arc sin [ m \frac{λ}{d} + sin ( \frac{λ}{π a} ) ] ) rad ;$$

and
for a relationship between the steering angle and seeding angle: θₛₜₑₑᵣ<θ_{seed};
where 1 is the wavelength of the seed beam and the one or more array beams, m is the diffraction order of the active grating (e.g., the seeded laser array), a is the diameter of individual VCSELs or PCSELs in the laser array, and d is the pitch or center-to-center distance of adjacent VCSELs or PCSELs in the laser array.

33. The system of any one of embodiments 17-32, wherein the seeding angle is an angle at which maximum off-axis seeding efficiency is achieved based on (a) the mode match between the seed beam and the laser array and (b) the transmission of a top mirror in the laser array.
34. A method comprising:
   propagating a seed beam emitted by a seed laser to an emitting side of a laser array comprising plurality of laser array emitters; and
   interfering the seed beam with one or more laser array beams emitted by one or more of the plurality of laser array emitters to lock the one or more array beams to a phase of the seed beam.
35. The method of embodiment 34, wherein propagating the seed beam to an emitting side of the laser array comprises:
   transmitting the seed beam to a reflector; and
   redirecting the seed beam to the emitting side of the laser array using the reflector.
36 The method of embodiment 34 or 35, wherein interfering the seed beam with a laser array beam emitted by a first laser array emitter of the plurality of laser array emitters comprises:
   receiving the seed beam with an optical routing element positioned on the emitting side of the laser array; and
   directing the seed beam to the first laser array emitter using the optical routing element.
37. The method of any one of embodiments 34-36, comprising changing a phase of the seed beam using one or more phase-changing elements prior to interfering the seed beam with at least one laser array beam of the one or more laser array beams.
38. The method of embodiment 37, wherein changing the phase of the seed beam using a phase-changing element of the one or more phase-changing elements comprises:
   transmitting the seed beam through the phase-changing element; and
   applying a voltage to the phase-changing element using a voltage source to cause a physical property of the phase-changing element to change, wherein the change in the physical property induces a change in the phase of the seed beam.
39. A laser array steering system comprising:
   a laser array comprising a plurality of laser array emitters;
   a micro-lens array positioned on an emitting side of the laser array and comprising a plurality of micro-lenses;
   an actuator connected to and configured to adjust a position of the micro-lens array relative to the laser array; and
   one or more processors configured to control the actuator.
40. The system of embodiment 39, wherein the actuator comprises a micro-electromechanical system.
41. The system of embodiment 39, wherein the actuator comprises a translation stage.
42. The system of embodiment 41, wherein the translation stage comprises a servo.
43. The system of embodiment 41, wherein the translation stage comprises a piezoelectric device.
44. The system of any one of embodiments 39-43, wherein the one or more processors are configured to cause the actuator to adjust the position of the micro-lens array based on a location of a target and a separation distance between the micro-lens array and the laser array.
45. The system of any one of embodiments 39-44, comprising one or more phase-changing elements positioned on an emitting side of the laser array and configured to induce phase changes in array beams emitted by one or more of the plurality of laser array emitters.
46. The system of embodiment 45, wherein the one or more phase-changing elements comprise a material having a physical property that changes when a voltage is applied to the material, wherein the change in the physical property of the material induces a change in the phase of an array beam when the array beam propagates through the phase-changing element.
47. The system of embodiment 46, wherein the one or more phase-changing elements are electro-optic modulators or piezoelectric devices.
48. The system of any one of embodiments 45-47, comprising a voltage source electrically coupled to the one or more phase-changing elements.
49. The system of embodiment 48, wherein the one or more processors are configured to control the voltage source.
50. The system of embodiment 49, wherein the one or more processors are wirelessly coupled to the voltage source.
51. The system of any one of embodiments 39-50, wherein the plurality of laser array emitters comprise vertical-cavity surface-emitting lasers (VCSELs) or photonic crystal surface-emitting lasers (PCSELs).
52. A method comprising:
   receiving one or more laser array beams emitted by one or more laser array emitters in a laser array at one or more micro-lenses of a micro-lens array positioned on an emitting side of the laser array; and
   adjusting a position of the micro-lens array relative to the laser array to steer the one or more laser array beams to a target location.
53. The method of embodiment 52, wherein adjusting the position of the micro-lens array relative to the laser array comprises transmitting a signal to an actuator connected to the micro-lens array using one or more processors.
54. The method of embodiment 53, wherein the signal causes the actuator to adjust the position of the micro-lens array based on a location of a target and a separation distance between the micro-lens array and the laser array.
55. The method of any one of embodiments 52-54, comprising changing a phase of a laser array beam of the one or more laser array beams using a phase-changing element.
56. The method of embodiment 55, wherein changing the phase of the laser array beam using the phase-changing element comprises:
   transmitting the laser array beam through the phase-changing element; and
   applying a voltage to the phase-changing element using a voltage source to cause a physical property of the phase-changing element to change, wherein the change in the physical property induces a change in the phase of the seed beam.
57. A self-seeding laser system comprising:
   a laser array comprising a plurality of laser array emitters; and
   a diffraction grating;
   wherein the laser array is configured to emit one or more array beams that are incident on the diffraction grating, and the diffraction grating is configured to retroreflect a retroreflected seed beam in a first direction back onto the laser array and to reflect an output beam in a second direction towards a target, such that the retroreflected seed beam interferes with the one or more array beams and locks the one or more array beams to a phase of the retroreflected seed beam.
58. The self-seeding laser system of embodiment 57, comprising an actuator configured to adjust a position of the diffraction grating to tune the system.
59. The self-seeding laser system of any one of embodiments 57-58, comprising:
   a mirror, wherein retroreflection of the retroreflected seed beam comprises reflection via a mirror; and
   an actuator configured to adjust a position of the mirror to tune the system.
60. A method comprising:
   propagating one or more array beams from a laser array comprising a plurality of laser array emitters to a diffraction grating;
   propagating a retroreflected seed beam in a first direction back from the diffraction grating onto the laser array; and
   propagating an output beam in a second direction from the diffraction grating towards a target;
   wherein the retroreflected seed beam interferes with the one or more array beams and locks the one or more array beams to a phase of the retroreflected seed beam.

The foregoing description, for the purpose of explanation, has been described with reference to specific embodiments and/or examples. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

As used herein, the singular forms “a”, “an”, and “the” include the plural reference unless the context clearly dictates otherwise. Reference to “about” a value or parameter or “approximately” a value or parameter herein includes (and describes) variations that are directed to that value or parameter per se. For example, description referring to “about X” includes description of “X”. It is understood that aspects and variations of the invention described herein include “consisting of” and/or “consisting essentially of” aspects and variations.

When a range of values or values is provided, it is to be understood that each intervening value between the upper and lower limit of that range, and any other stated or intervening value in that stated range, is encompassed within the scope of the present disclosure. Where the stated range includes upper or lower limits, ranges excluding either of those included limits are also included in the present disclosure.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

Any of the systems, methods, techniques, and/or features disclosed herein may be combined, in whole or in part, with any other systems, methods, techniques, and/or features disclosed herein.

1. A laser system comprising:
a laser array comprising a plurality of laser array emitters;
a seed laser; and
a waveguide bordering the laser array and configured to optically couple the seed laser to the plurality of laser array emitters,
wherein the seed laser is configured to emit a seed beam that interferes with one or more array beams emitted by the one or more of the plurality of laser array emitters and locks the one or more array beams to a phase of the seed beam.

2. The system of claim 1, wherein the waveguide is linear in shape.

3. The system of claim 1, wherein the laser array is a two-dimensional laser array.

4. The system of claim 1, wherein the waveguide comprises one or more partial pass deflectors configured to deflect the seed beam to one or more spatial regions of the laser array.

5. The system of claim 1, comprising one or more phase-changing elements positioned in an optical path of the seed laser and configured to change the phase of the seed beam.

6. The system of claim 5, wherein each phase-changing element of the one or more phase-changing elements is positioned next to a laser array emitter of the plurality of laser array emitters.

7. The system of claim 5, wherein the one or more phase-changing elements comprise a material having a physical property that changes when a voltage is applied to the material, wherein the change in the physical property of the material induces a change in the phase of the seed beam when the seed beam propagates through the phase-changing element.

8. The system of claim 7, wherein the one or more phase-changing elements are electro-optic modulators or piezoelectric devices.

9. The system of claim 5, comprising:
a voltage source electrically coupled to the one or more phase changing elements; and
one or more processors configured to control the voltage source.

10. The system of claim 9, wherein the one or more processors are wirelessly coupled to the voltage source.

11. The system of claim 1, wherein the plurality of laser array emitters comprise vertical-cavity surface-emitting lasers (VCSELs) or photonic crystal surface-emitting lasers (PCSELs).

12. The system of claim 1, wherein the waveguide comprises aluminum gallium arsenide.

13. A method comprising:
propagating a seed beam emitted by a seed laser through a waveguide bordering a laser array comprising a plurality of laser array emitters; and
interfering the seed beam with one or more laser array beams emitted by one or more of the plurality of laser array emitters to lock the one or more laser array beams to a phase of the seed beam.

14. The method of claim 13, comprising deflecting the seed beam to one or more spatial regions of the laser array using one or more partial-pass deflectors embedded in the waveguide.

15. The method of claim 13, comprising changing a phase of the seed beam using one or more phase-changing elements prior to interfering the seed beam with at least one laser array beam of the one or more laser array beams.

16. The method of claim 15, wherein changing the phase of the seed beam using a phase-changing element of the one or more phase-changing elements comprises:
transmitting the seed beam through the phase-changing element; and
applying a voltage to the phase-changing element using a voltage source to cause a physical property of the phase-changing element to change, wherein the change in the physical property induces a change in the phase of the seed beam.
